(19) United States
(12) Patent Application Publication
(10) Pub. No.: US 2011/0063926 A1
(43) Pub. Date: Mar. 17, 2011

(54) Write Through Speed Up for Memory Circuit

(75) Inventors: Stefan G. Block, Munich (DE); Ralph Sommer, Munich (DE); Juergen Dirks, Holzkirchen (DE)

(73) Assignee: LSI CORPORATION, Milpitas, CA (US)

(21) Appl. No.: 12/558,615

(22) Filed: Sep. 14, 2009

(51) Int. Cl. G11C 7/00; G11C 8/00

(52) U.S. Cl. 365/189.011; 365/230.01

(57) ABSTRACT

A method of performing a write-through operation with a memory circuit having a write enable line, a write address line, a data in line, a read address line, a data out line, a bit array, a comparator, and a mux. A write address is received on the write address line, a read address is received on the read address line, data is received on the data in line. The comparator determines as a first condition whether the write address is identical to the read address, and determines as a second condition whether the write enable line is enabled. When both the first condition and the second condition are met, the comparator signals the mux to directly output the data receiving on the data in line on the data out line without writing the data to the bit array. In this manner, the memory circuit checks to determine whether a write-through operation is called for. If it is, then the mux sends the data on the data in line directly to the data out line, instead of retrieving data from the bit array of the memory, such as through the read decoder, which would take much longer.

### FIELD

This invention relates to the field of integrated circuits. More particularly, this invention relates to improving the write through performance for random access memory and large block random access memory.

### BACKGROUND

The most critical timing path inside of RAMs and LBRAMs (latch based memories, flip flop arrays, and register arrays), all of which are generally referred to as a “memory” or “memory circuit” herein, is the path from the write clock to the dataout in the so-called write-through mode. In that mode, the address to which data is written inside the memory is also read out at the same time. This path is usually the slowest path through the memory, and so the operation is extremely slow.

FIG. 1 depicts a functional block diagram of a prior art RAM/LBRAM memory structure (principal synchronous structure, with no pipe-line). The maximum timing arc for the memory is evident from the following steps:
1. READ:
   READCLOCK→READ address register→READ decoder DATAOUT
   or
   BIT ARRAY→READ decoder→DATAOUT
2. WRITE:
   WRITECLOCK→DATAIN register→BIT ARRAY
   or
   WRITECLOCK→WRITE address register→Write decoder→BIT ARRAY
   or
   WRITECLOCK→WRITE enable register→Write decoder→BIT ARRAY
3. WRITE THROUGH
   READCLOCK→READ address→register→READ decoder→DATAOUT
   or
   WRITECLOCK→DATAIN register→BIT ARRAY→READ decoder→DATAOUT
   or
   WRITECLOCK→WRITE address register→Write decoder→BIT ARRAY →READ decoder→DATAOUT
   or
   WRITECLOCK→WRITE enable register→Write decoder→BIT ARRAY→READ decoder→DATAOUT

Thus, as mentioned above, the WRITE THROUGH mode is the most timing-critical mode for the memory.

Prior art designs have attempted to resolve this problem by adding external logic to avoid a write-through and handle the situation in some other manner. However, the disadvantages of these existing solutions are the logic overhead that they require. In addition, these solutions need to add registers to the design, in order to make the external bypass occur in the correct clock-cycle.

What is needed, therefore, is a memory design that overcomes problems such as those described above, at least in part.

### SUMMARY

The above and other needs are met by a method of performing a write-through operation with a memory circuit having a write enable line, a write address line, a data in line, a read address line, a data out line, a bit array, a comparator, and a mux. A write address is received on the write address line, a read address is received on the read address line, data is received on the data in line. The comparator determines as a first condition whether the write address is identical to the read address, and determines as a second condition whether the write enable line is enabled. When both the first condition and the second condition are met, the comparator signals the mux to directly output the data receiving on the data in line on the data out line without writing the data to the bit array.

In this manner, the memory circuit checks to determine whether a write-through operation is called for. If it is, then the mux sends the data on the data in line directly to the data out line, instead of retrieving data from the bit array of the memory, such as through the read decoder, which would take much longer.

According to another aspect of the invention there is described a memory circuit with a write enable line for receiving a write enable signal, a write address line for receiving a write address, a data in line for receiving data into the memory circuit, a read address line for receiving a read address within the memory circuit, a data out line for outputting data from the memory circuit, a bit array for storing data within the memory circuit, and a data out line for outputting data from the memory circuit. A mux receives data from both the bit array and the data in line, and selectively provides as output on the data out line (a) data received directly from the data in line, and (b) data stored at the read address within the bit array of the memory circuit. A comparator determines as a first condition whether the write address is identical to the read address, and determines as a second condition whether the write enable line is enabled. When both the first condition and the second condition are met, the comparator signals the mux to provide as output on the data out line the data received directly from the data in line.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a prior art design for a memory.

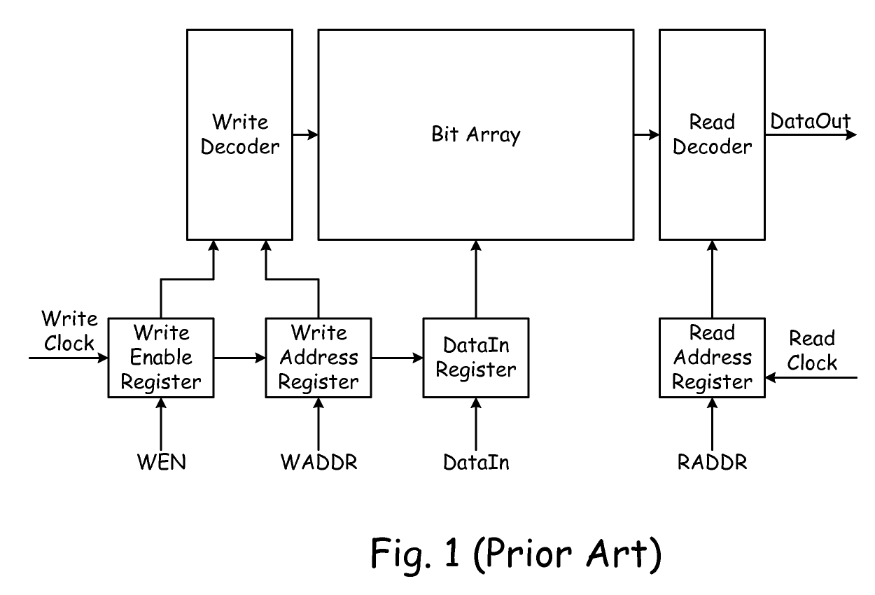

FIG. 2 is a memory according to an embodiment of the present invention.

### DETAILED DESCRIPTION

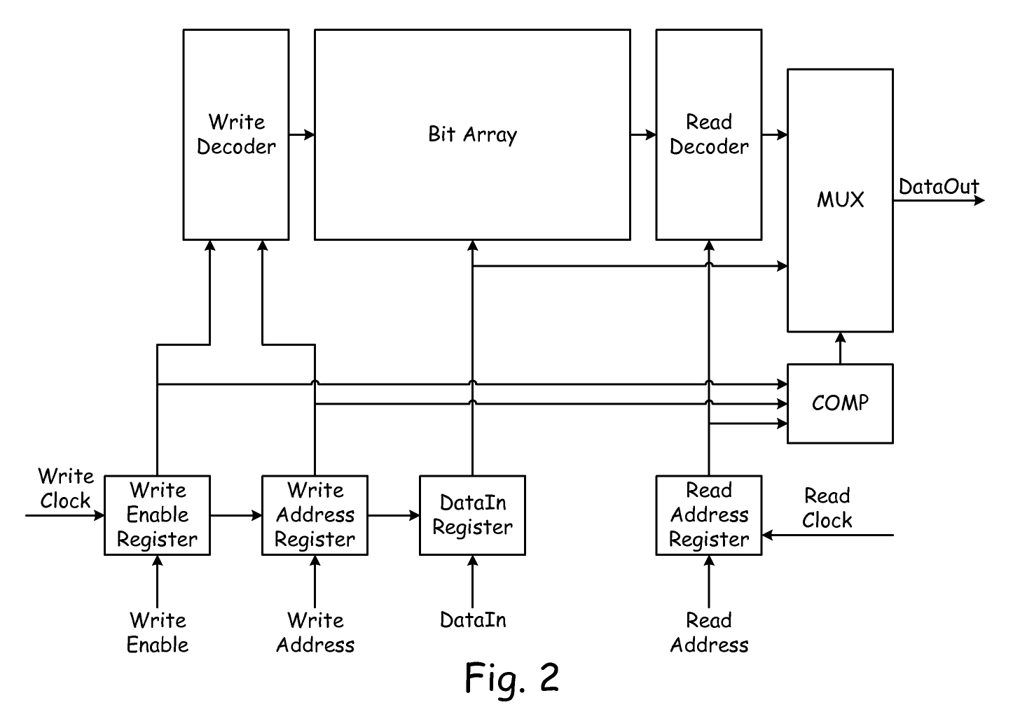

With reference now to FIG. 2, there is depicted a functional block diagram for a RAM/LBRAM according to an embodiment of the present invention. This embodiment has the following maximum timing arc:
1. READ:
   READCLOCK→READ address register→READ decoder→MUX→DATAOUT
   or
   BIT ARRAY→READ decoder→DATAOUT
2. WRITE:
   WRITECLOCK→DATAIN register→BIT ARRAY
   or
   WRITECLOCK→WRITE address register→Write decoder→BIT ARRAY
   or
   WRITECLOCK→WRITE enable register→Write decoder→BIT ARRAY
   3. WRITE THROUGH:
   READCLOCK→READ address register→COMP→MUX→DATAOUT
   or
   WRITECLOCK→DATAIN register→MUX→DATAOUT
   or
   WRITECLOCK→WRITE address register→COMP→MUX→DATAOUT
   or
   WRITECLOCK→WRITE enable register→COMP→MUX→DATAOUT

This enhanced memory structure is created by adding a few gates inside the RAM/LBRAM. However, no additional registers are required. This design, as indicated above, speeds up the write-through mode. A comparator is used to compare the read and write address, which determines when a write-through operation is occurring. If the read and write addresses are identical and the write-enable line is active, then the DataIn is muxed directly to the DataOut line of the memory, which greatly increases the speed of the memory in the write-through operation, with a minimal additional gate overhead.

The foregoing description of preferred embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A method of performing a write-through operation with a memory circuit having a write enable line, a write address line, a data in line, a read address line, a data out line, a bit array, a comparator, and a mux, the method comprising the steps of:
receiving a write address on the write address line,
receiving a read address on the read address line,
receiving data on the data in line,
with the comparator, determining as a first condition whether the write address is identical to the read address, and determining as a second condition whether the write enable line is enabled, and
when both the first condition and the second condition are met, signaling the mux with the comparator to directly output the data receiving on the data in line on the data out line without writing the data to the bit array.

2. A memory circuit comprising:
a write enable line for receiving a write enable signal,
a write address line for receiving a write address,
a data in line for receiving data into the memory circuit,
a read address line for receiving a read address within the memory circuit,
a data out line for outputting data from the memory circuit,
a bit array for storing data within the memory circuit,
a data out line for outputting data from the memory circuit,
a mux for receiving data from both the bit array and the data in line, and for selectively providing as output on the data out line (a) data received directly from the data in line and (b) data stored at the read address within the bit array of the memory circuit, and
a comparator for determining as a first condition whether the write address is identical to the read address, and determining as a second condition whether the write enable line is enabled, and when both the first condition and the second condition are met, for signaling the mux to provide as output on the data out line the data received directly from the data in line.
